(19) United States
(12) Patent Application Publication
(10) Pub. No.: US 2007/0201286 A1
(43) Pub. Date: Aug. 30, 2007

(54) INPUT CIRCUIT OF A SEMICONDUCTOR MEMORY DEVICE AND METHOD OF CONTROLLING THE SAME

(75) Inventor: Reum Oh, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/678,480

(22) Filed: Feb. 23, 2007

(30) Foreign Application Priority Data
Feb. 24, 2006 (KR) 2006-0018063

(51) Int. Cl. G11C 7/10; G11C 7/00

(52) U.S. Cl. 365/193; 365/189.05; 365/194

(57) ABSTRACT

An input circuit of a semiconductor memory device includes a data strobe circuit configured to buffer a data strobe signal to generate a first internal strobe signal and to generate a second internal strobe signal in response to the first internal strobe signal and an operating mode of the semiconductor memory device, and a data input circuit configured to perform data processing on input data in response to the first internal strobe signal, the second internal strobe signal and the operating mode to generate internal write data.

### CROSS-REFERENCE TO RELATED APPLICATIONS

This application claims priority under 35 USC §119 to Korean Patent Application No. 2006-18063, filed on Feb. 24, 2006 in the Korean Intellectual Property Office (KIPO), the disclosure of which is incorporated herein in its entirety by reference.

### BACKGROUND

1. Technical Field

This disclosure relates to a semiconductor memory device and a method of controlling the semiconductor memory device, and more particularly to a semiconductor memory device having an input circuit structure capable of increasing test capabilities and a method of controlling the input circuit of the semiconductor memory device.

2. Description of the Related Art

Double data rate (DDR) dynamic random-access memories (DRAM) are widely used as semiconductor memory devices. DDR DRAM performs two data operations in one clock cycle, while single data rate (SDR) DRAM performs one data operation in one clock cycle. Therefore, the processing speed of the DDR DRAM is two times faster than the SDR DRAM.

DDR DRAM is difficult to test using a tester that has low speed because the processing speed of data of the DDR DRAM is relatively fast. For example, it is difficult to test a DRAM that operates at the speed of 800 MHz using a tester that has a speed of 400 MHz.

In a conventional DRAM, a clock signal is generated using a phase-locked loop (PLL) having a frequency two times higher than a data strobe signal that is input to the DRAM. Then, the DRAM is tested using the clock signal. However, in the test mode, alternating current (AC) parameters, such as a data setup/hold time (tDS/DH) and DQSS, should be adjusted in order to perform data processing, such as sampling and time delaying using the clock signal generated by the PLL, at a frequency two times higher than the data strobe signal. Here, DQSS is a parameter that is determined by a difference between an internal strobe signal and an internal clock signal.

Accordingly, a semiconductor memory device having the conventional input/output structure has limited test capabilities.

### SUMMARY

An embodiment includes input circuit of a semiconductor memory device including a data strobe circuit configured to buffer a data strobe signal to generate a first internal strobe signal and to generate a second internal strobe signal in response to the first internal strobe signal and an operating mode of the semiconductor memory device, and a data input circuit configured to perform data processing on input data in response to the first internal strobe signal, the second internal strobe signal and the operating mode to generate internal write data.

Another embodiment includes a method of controlling an input circuit of a semiconductor memory device including receiving input data, generating a first internal strobe signal in response to a data strobe signal, delaying bits of the input data in response to the first internal strobe signal and an operating mode of the semiconductor memory device, generating a second internal strobe signal in response to the first internal strobe signal and the operating mode, sampling the delayed bits using the second internal strobe signal, and storing the sampled bits.

### BRIEF DESCRIPTION OF THE DRAWINGS

FIG. 1 is a circuit diagram illustrating an example of a semiconductor memory device that includes a data write path according to an embodiment.

FIG. 2 is a circuit diagram illustrating an example of a variable delay circuit included in the semiconductor memory device shown in FIG. 1.

FIG. 3 is a timing diagram illustrating an example of a process in which control signals are generated when the semiconductor memory device shown in FIG. 1 is operated in a normal mode.

FIG. 4 is a timing diagram illustrating an example of an operation of the semiconductor memory device shown in FIG. 1 when the semiconductor memory device is operated in a normal mode.

FIG. 5 is a timing diagram illustrating an example of a process in which control signals are generated when the semiconductor memory device shown in FIG. 1 is operated in a test mode.

FIG. 6 is a timing diagram illustrating an example of an operation of the semiconductor memory device shown in FIG. 1 when the semiconductor memory device is operated in a test mode.

FIG. 7 is a circuit diagram illustrating a semiconductor memory device that includes a data write path according to another embodiment.

### DETAILED DESCRIPTION

Embodiments will be described more fully with reference to the accompanying drawings. Embodiments may, however, take many different forms and should not be construed as limited to the embodiments set forth herein. Rather, these embodiments are provided so that this disclosure will be thorough and complete, and will fully convey the scope of the following claims to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

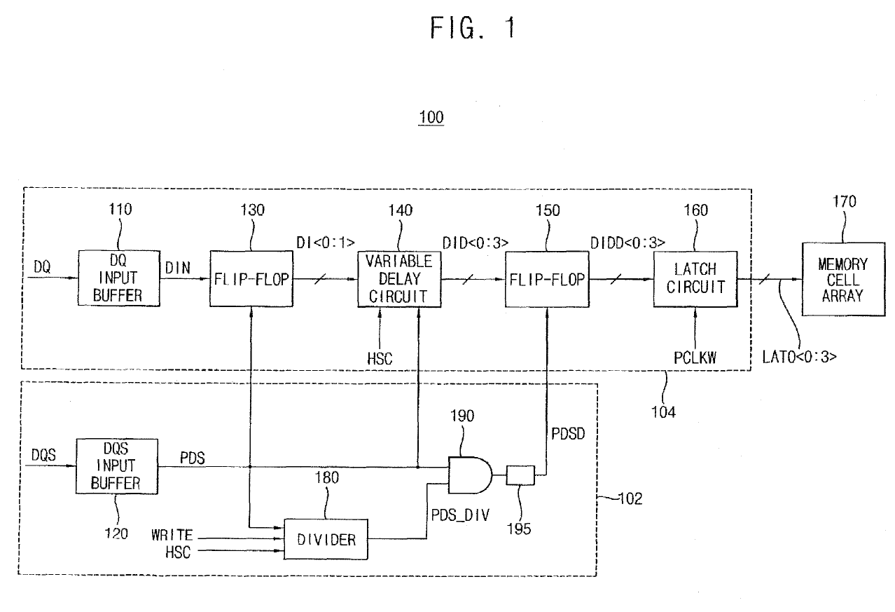

FIG. 1 is a circuit diagram illustrating a semiconductor memory device that includes a data write path according to an embodiment. The semiconductor memory device 100 includes a data strobe circuit 102 and a data input circuit 104. The data strobe circuit 102 includes a data strobe buffer 120, a frequency divider 180, an AND gate 190, and a delay unit 195. The data input circuit 104 includes a data input buffer 110, a first flip-flop 130, a variable delay circuit 140, a second flip-flop 150, and a latch circuit 160. The semiconductor memory device 100 also includes a memory cell array 170.

The data strobe circuit 102 is configured to buffer a data strobe signal DQS to generate a first internal strobe signal PDS. Furthermore, the data strobe circuit 102 is configured to generate a second internal strobe signal PDSD having different enable points of time in a normal mode and in a test mode on the basis of the first internal strobe signal PDS and an operating mode of the semiconductor memory device. The data input circuit 104 is configured to perform data processing on external data DQ in response to the first internal strobe signal PDS and the second internal strobe signal PDSD to generate internal write data LATO<0:3>.

The data strobe buffer 120 is configured to buffer the data strobe signal DQS to generate the first internal strobe signal PDS. The frequency divider 180 is configured to divide a frequency of the first internal strobe signal PDS by a first dividing ratio in the normal mode and by a second dividing ratio in a test mode in response to a write signal WRITE and a test mode signal HSC to generate a frequency-divided strobe signal PDS_DIV. The AND gate 190 is configured to perform a logical AND operation on the first internal strobe signal PDS and the frequency-divided strobe signal PDS_DIV. The delay unit 195 is configured to delay an output signal of the AND gate 190 to generate the second internal strobe signal PDSD. The delay unit 195 may be incorporated into the AND gate 190.

The data input buffer 110 is configured to buffer the external data DQ to generate first internal data DIN. The first flip-flop 130 is configured to sample the first internal data DIN in response to the first internal strobe signal PDS to generate second internal data DI<0:1> having 2 bits. The variable delay circuit 140 is configured to delay each bit of the second internal data DI<0:1> in response to the first internal strobe signal PDS and the test mode signal HSC to generate third internal data DID<0:3> having 4 bits. The variable delay circuit 140 can vary delay times of the bits in response to the test mode signal HSC. The second flip-flop 150 is configured to rearrange the third internal data DID<0:3> in response to the second internal strobe signal PDSD to generate fourth internal data DIDD<0:3>. The latch circuit 160 is configured to latch the fourth internal data DIDD<0:3> in response to an internal clock signal PCLKW.

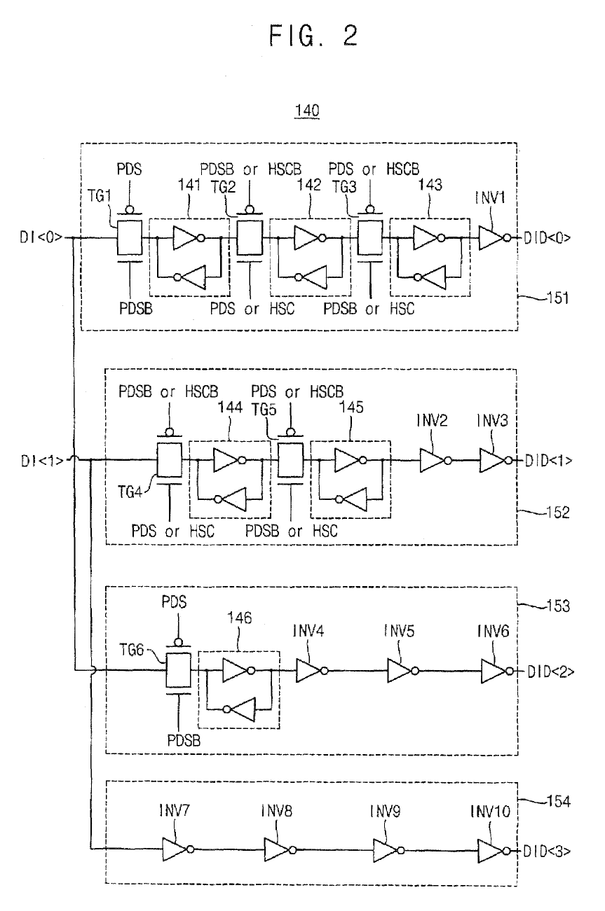

FIG. 2 is a circuit diagram illustrating an example of a variable delay circuit 140 included in the semiconductor memory device 100 shown in FIG. 1. The variable delay circuit 140 includes a first delay path 151, a second delay path 152, a third delay path 153, and a fourth delay path 154. In addition, PDSB denotes an inverted signal of PDS, and HSCB denotes an inverted signal of HSC.

Controls of some transmission gates, e.g. TG2, TG3, TG4 and TG5, are illustrated as including PDS or HSC. Such transmission gates can use either PDS or HSC as the control signal depending on the operating mode of the semiconductor memory device.

The first delay path 151 is configured to delay a first bit DI<0> of the second internal data by a first delay time to generate a first bit DID<0> of the third internal data. The second delay path 152 is configured to delay a second bit DI<1> of the second internal data by a second delay time to generate a second bit DID<1> of the third internal data. The third delay path 153 is configured to delay the first bit DI<0> of the second internal data by a third delay time to generate a third bit DID<2> of the third internal data. The fourth delay path 154 is configured to delay the second bit DI<1> of the second internal data by a fourth delay time to generate a fourth bit DID<3> of the third internal data. Although the fourth delay path has been described as delaying by a fourth delay time, the fourth delay time can, but need not be zero relative to the first, second, and third delay times.

In the example of FIG. 2, the variable delay circuit 140 can vary delay times of the bits of the third internal data DID<0:3> in response to the test mode signal HSC. For example, control signal PDS or HSC of the transmission gate TG 2 may be an output signal of an OR gate that performs an OR operation on the first internal strobe signal PDS and the test mode signal HSC. If the test mode signal HSC is disabled to logic low in a normal mode, the output signal of the OR gate corresponds to the first internal strobe signal PDS. The transmission gate TG2 is operated in response to the first internal strobe signal PDS in the normal mode to delay an input signal thereof by 0.5 clock period. One the other hand, if the test mode signal HSC is enabled to logic high in a test mode, the output signal of the OR gate corresponds to the test mode signal HSC of logical high level. The transmission gate TG2 is operated in response to the test mode signal HSC in the test mode to pass the input signal without delay.

In the normal mode, the first bit DID<0> of the third internal data is generated by delaying the first bit DI<0> of the second internal data by 1.5 clock period. The second bit DID<1> of the third internal data is generated by delaying the second bit DI<1> of the second internal data by 1 clock period. The third bit DID<2> of the third internal data is generated by delaying the first bit DI<0> of the second internal data by 0.5 clock period. The fourth bit DID<3> of the third internal data is generated without delaying the second bit DI<1> of the second internal data.

In the test mode, the first bit DID<0> and the third bit DID<2> of the third internal data are generated by delaying the first bit DI<0> of the second internal data by 0.5 clock period because the transmission gates TG2 and TG3 pass respective input signals thereof without delay in response to the test mode signal HSC instead of the first internal strobe signal PDS. The second bit DID<1> and the fourth bit DID<3> of the third internal data are generated without delaying the second bit DI<1> of the second internal data because the transmission gates TG4 and TG5 pass respective input signals thereof without delay in response to the test mode signal HSC instead of the first internal strobe signal PDS.

The first delay path 151 includes a first transmission gate TG1, a second transmission gate TG2, a third transmission gate TG3, a first latch 141, a second latch 142, a third latch 143, and a first inverter INV1.

The first transmission gate TG1 transfers the first bit DI<0> of the second internal data in response to the first internal strobe signal PDS and an inverted signal PDSB of the first internal strobe signal PDS. The first latch 141 latches an output signal of the first transmission gate TG1. The second transmission gate TG2 transfers an output signal of the first latch 141 in response to the first internal strobe signal PDS and the inverted signal PDSB of the first internal strobe signal PDS, or a test mode signal HSC and an inverted signal HSCB of the test mode signal HSC. The second latch 142 latches an output signal of the second transmission gate TG2. The third transmission gate TG3 transfers an output signal of the second latch 142 in response to the first internal strobe signal PDS and the inverted signal PDSB of the first internal strobe signal PDS, or the test mode signal HSC and the inverted signal HSCB of the test mode signal HSC. The third latch 143 latches an output signal of the third transmission gate TG3. The first inverter INV1 inverts an output signal of the third latch 143.

The second delay path 152 includes a fourth transmission gate TG4, a fifth transmission gate TG5, a fourth latch 144, a fifth latch 145, a second inverter INV2, and a third inverter INV3.

The fourth transmission gate TG4 transfers the second bit DI<1> of the second internal data in response to the first internal strobe signal PDS and the inverted signal PDSB of the first internal strobe signal PDS, or the test mode signal HSC and the inverted signal HSCB of the test mode signal HSC. The fourth latch 144 latches an output signal of the fourth transmission gate TG4. The fifth transmission gate TG5 transfers an output signal of the fourth latch 144 in response to the first internal strobe signal PDS and the inverted signal PDSB of the first internal strobe signal PDS, or the test mode signal HSC and the inverted signal HSCB of the test mode signal HSC. The fifth latch 145 latches an output signal of the fifth transmission gate TG5. The second inverter INV2 inverts an output signal of the fifth latch 145. The third inverter INV3 inverts an output signal of the second inverter INV2.

The third delay path 153 includes a sixth transmission gate TG6, a sixth latch 146, a fourth inverter INV4, a fifth inverter INV5, and a sixth inverter INV6.

The sixth transmission gate TG6 transfers the first bit DI<1> of the second internal data in response to the first internal strobe signal PDS and an inverted signal PDSB of the first internal strobe signal PDS. The sixth latch 146 latches an output signal of the sixth transmission gate TG6. The fourth inverter INV4 inverts an output signal of the sixth latch 146. The fifth inverter INV5 inverts an output signal of the fourth inverter INV4. The sixth inverter INV6 inverts an output signal of the fifth inverter INV5.

The fourth delay path 154 includes a seventh inverter INV7, an eighth inverter INV8, a ninth inverter INV9, and a tenth inverter INV10.

The seventh inverter INV7 inverts the second bit DI<1> of the second internal data. The eighth inverter INV8 inverts an output signal of the seventh inverter INV7. The ninth inverter INV9 inverts an output signal of the eighth inverter INV8. The tenth inverter INV10 inverts an output signal of the ninth inverter INV9.

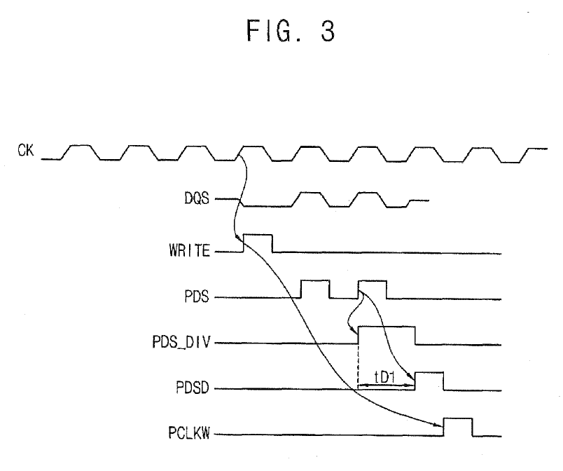

FIG. 3 is a timing diagram illustrating an example of a process in which control signals are generated when the semiconductor memory device 100 shown in FIG. 1 is operated in a normal mode.

Referring to FIG. 3, the data strobe signal DQS is generated in synchronization with the clock signal CK. The write signal WRITE is enabled in response to the clock signal CK. The internal clock signal PCLKW is enabled in response to the write signal WRITE after a predetermined delay time. The first internal strobe signal PDS is enabled in response to the data strobe signal DQS. The frequency-divided strobe signal PDS_DIV is enabled in response to a rising edge of a second pulse of the first internal strobe signal PDS. The second internal strobe signal PDSD is enabled in response to the rising edge of the second pulse of the first internal strobe signal PDS after a delay time tD1 from the rising edge of the frequency-divided strobe signal PDS_DIV.

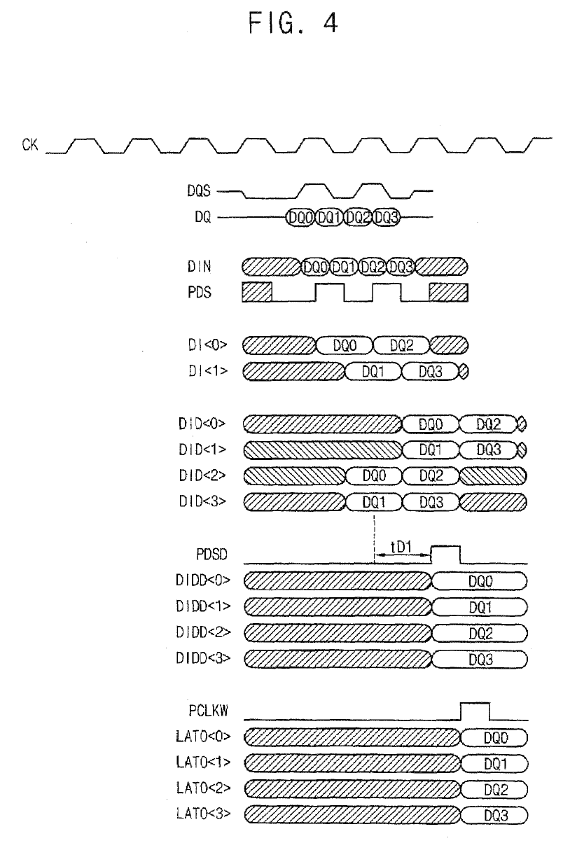

FIG. 4 is a timing diagram illustrating an example of an operation of the semiconductor memory device 100 shown in FIG. 1 when the semiconductor memory device 100 is operated in a normal mode.

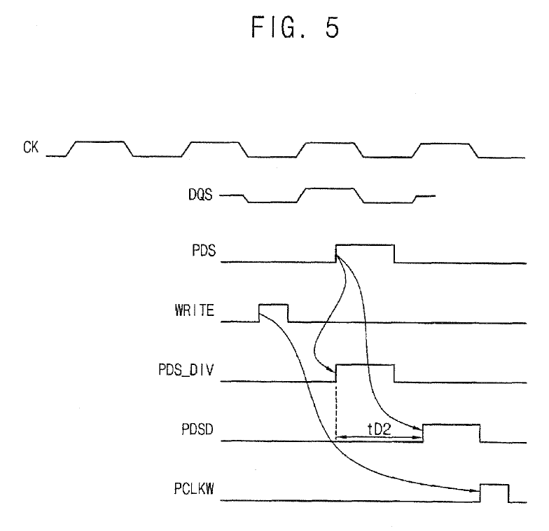

FIG. 5 is a timing diagram illustrating an example of a process in which control signals are generated when the semiconductor memory device 100 shown in FIG. 1 operates in a test mode.

Referring to FIG. 5, the data strobe signal DQS is generated in synchronization with the clock signal CK. The internal clock signal PCLKW is enabled in response to the write signal WRITE after a predetermined delay time. The first internal strobe signal PDS is enabled in response to the data strobe signal DQS. The frequency-divided strobe signal PDS_DIV is enabled in response to a rising edge of the first internal strobe signal PDS. The second internal strobe signal PDSD is enabled in response to the rising edge of the first internal strobe signal PDS after a delay time tD2 from the rising edge of the frequency-divided strobe signal PDS_DIV.

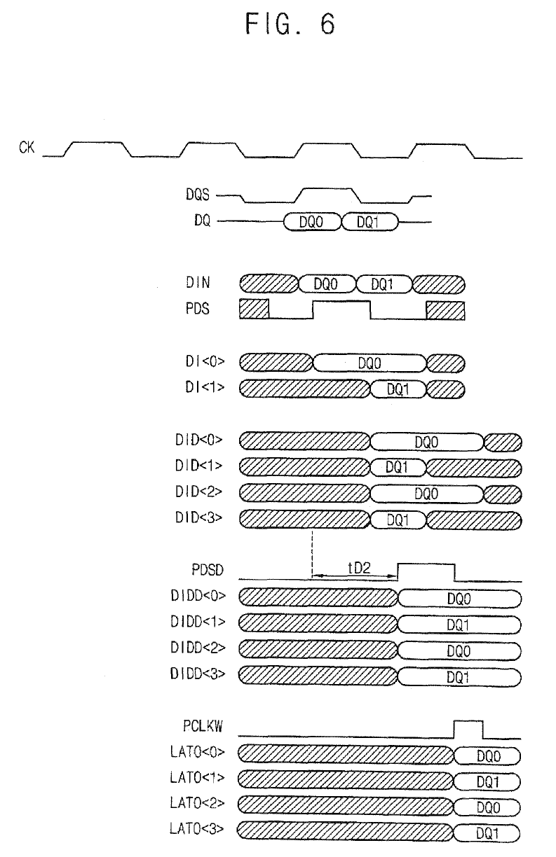

FIG. 6 is a timing diagram illustrating an example of an operation of the semiconductor memory device 100 shown in FIG. 1 when the semiconductor memory device 100 is operated in a test mode.

Hereinafter, operations of the semiconductor memory device 100 according to an embodiment will be described with reference to FIG. 1 to FIG. 6.

The semiconductor memory device 100 is configured to perform data processing of the data DQ input to the semiconductor memory device 100 in response to the data strobe signal DQS input to the semiconductor memory device 100, to generate the internal write data LAT<0:3>. Therefore, the semiconductor memory device 100 may generate the internal write data LAT<0:3> by performing data processing such as sampling, time delaying, and latching on the data DQ input from the exterior without considering skew between clock signals and data to be written.

The first internal strobe signal PDS, which is a data strobe signal DQS buffered by the data strobe buffer 120, is divided by the frequency divider 180. The AND gate 190 performs a logical AND operation on the first internal strobe signal PDS and the frequency-divided strobe signal PDS_DIV. The delay unit 195 is configured to delay an output signal of the AND gate 190 to generate the second internal strobe signal PDSD.

In a normal mode, that is, when the write signal WRITE is enabled and the test mode signal HSC is disabled, the frequency divider 180 divides a frequency of the first internal strobe signal PDS by a first dividing ratio to generate the frequency-divided strobe signal PDS_DIV.

In a test mode, that is, when both of the write signal WRITE and the test mode signal TMS are enabled, the frequency divider 180 divides a frequency of the first internal strobe signal PDS by a second dividing ratio to generate the frequency-divided strobe signal PDS_DIV. The AND gate 190 performs a logical AND operation on the first internal strobe signal PDS and the frequency-divided strobe signal PDS_DIV to generate the second internal strobe signal PDSD.

The first dividing ratio and the second dividing ratio may be determined on the basis of a burst length (BL). For example, the first dividing ratio may be half of the burst length (BL) and the second dividing ratio may be a fourth of the burst length (BL).

The first flip-flop 130 is controlled by the first internal strobe signal PDS. In FIG. 4, four bits DQ0, DQ1, DQ2, and DQ3 are present in the first internal data DIN. In FIG. 6, two bits DQ0 and DQ1 are present in the first internal data DIN. In both cases, the first internal strobe signal PDS is used to sample the first internal data DIN to generate the second internal data DI<0:1>, with alternating bits of the first internal data DIN appearing on the individual second internal data DI<0> and DI<1>.

The variable delay circuit 140 transfers the second internal data DI<0:1> having two bits through delay paths that have different delay times to generate the third internal data DID<0:3> having four bits. The first bit DI<0> of the second internal data DI<0:1> is used to generate the first and third bits DID<0> and DID<2> of the third internal data DID<0:3>, and the second bit DI<1> of the second internal data DI<0:1> is used to generate the second and third bits DID<1> and DID<3> of the third internal data DID<0:3>.

In an embodiment, the delays through the first, second, third, and fourth delay paths 151, 152, 153, and 154 are such that valid data of the second internal data DI<0:1> is present in each of the third internal data DID<0:3> aligned to be sampled by the second internal strobe signal PDSD. In the example of FIG. 4, each of the bits in the first internal data DIN is present in the third internal data DID<0:3>. In FIG. 6, since the first internal data DIN only had two bits, bits DQ0 and DQ1 are duplicated for the four bits of the third internal data DID<0:3> in the test mode.

The second flip-flop 150 is configured to retime the third internal data DID<0:3> in response to the second internal strobe signal PDSD to generate the fourth internal data DIDD<0:3>. In the normal mode, since DID<0> and DID<2> were generated from DI<0> having DQ0 and DQ2 and the variable delay circuit 140 delayed DI<0> more so to generate DID<0> than DID<2>, DQ0 on DID<0> is aligned with DQ2 on DID<2> to be retimed with the second internal strobe signal PDSD. Thus, DIDD<0> and DIDD<2> become DQ0 and DQ2, respectively, in response to the second internal strobe signal PDSD. Similarly, DIDD<1> and DIDD<3> become DQ1 and DQ3, respectively. Similarly, in the test mode where DID<0> and DID<2> are DQ0, and DID<1> and DID<3> are DQ1, DIDD<O> and DIDD<2> become DQ0 and DIDD<1> and DIDD<3> become DQ1.

The latch circuit 160 latches the fourth internal data DIDD<0:3> in response to an internal clock signal PCLKW. The internal write data LATO<0:3>, which is an output signal of the latch circuit 160, is applied to the memory cell array 170.

Referring to FIG. 3 and FIG. 5, the frequency-divided strobe signal PDS_DIV has a frequency that is one half of the frequency of the first internal strobe signal PDS in the normal mode. The second internal strobe signal PDSD is enabled after about one clock period with respect to a rising edge of the frequency-divided strobe signal PDS_DIV. However, in the test mode, the frequency-divided strobe signal PDS_DIV has the same period as the first internal strobe signal PDS, and the second internal strobe signal PDSD is enabled after about three-quarters of one clock period with respect to a rising edge of the frequency-divided strobe signal PDS_DIV, The delay times tD1 and tD2 of the delay unit 195 are adjusted such that the flip-flop can sample the aligned bits of the third internal data DID<0:3> in response to the second internal strobe signal PDSD.

As described above, the semiconductor memory device 100 according to an embodiment shown in FIG. 1 is configured to control the first flip-flop 130 and the variable delay circuit 140 included in the data input circuit 104 using the first internal strobe signal PDS that is a buffered signal of the data strobe signal DQS. The data strobe signal DQS is received from the exterior (e.g., from a memory test device) in the test mode. Furthermore, the semiconductor memory device 100 according to an embodiment shown in FIG. 1 is configured to divide the first internal strobe signal PDS by BL/2 in the normal mode, but by BL/4 in the test mode without using a doubled clock signal from a PLL. Furthermore, the parameter tDS/DH may not be changed because the first internal data DIN is sampled using the first internal strobe signal PDS both in the normal mode and in the test mode. Furthermore, as noted from FIG. 3 and FIG. 5, the time period between a rising edge of the second internal strobe signal PDSD and a rising edge of the internal clock signal PCLKW in the test mode is a half clock longer than the time period in the normal mode.

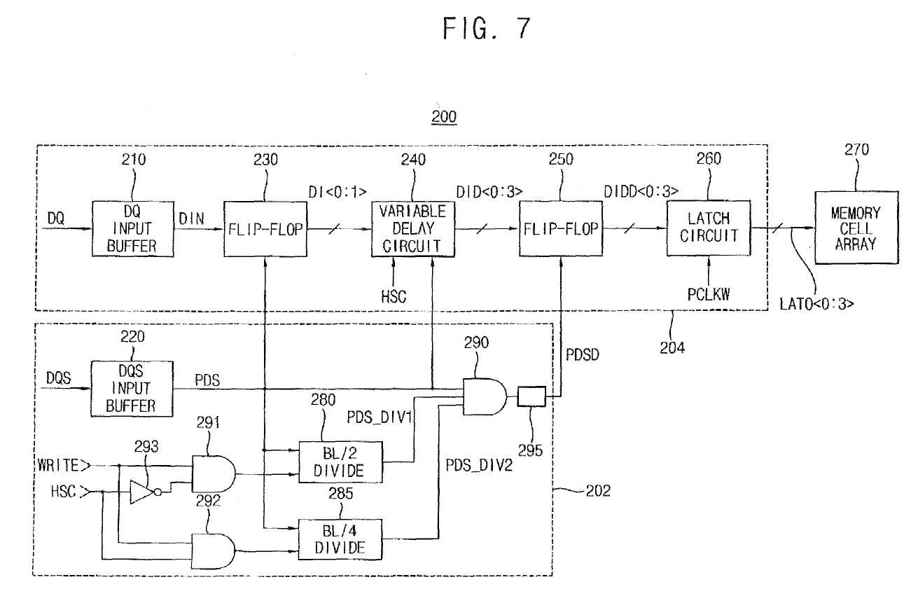

FIG. 7 is a circuit diagram illustrating a semiconductor memory device that includes a data write path according to another embodiment. The semiconductor memory device 200 includes a data strobe circuit 202 and a data input circuit 204. The data strobe circuit 202 includes a data strobe buffer 220, a first frequency divider 280, a second frequency divider 285, a first AND gate 290, a inverter 293, a second AND gate 291, a third AND gate 292 and a delay unit 295. The data input circuit 204 includes a data input buffer 210, a first flip-flop 230, a variable delay circuit 240, a second flip-flop 250, and a latch circuit 260. The semiconductor memory device 200 also includes a memory cell array 270. The inverter 293 and the second AND gate 291 may be included in the first frequency divider 280, and the third AND gate 292 may be included in the second frequency divider 285.

The data strobe circuit 202 is configured to buffer a data strobe signal DQS to generate a first internal strobe signal PDS. Further, the data strobe circuit 202 is configured to generate a second internal strobe signal PDSD having different enable points of time in a normal mode and in a test mode on the basis of the first internal strobe signal PDS and an operating mode of the semiconductor memory device. The data input circuit 204 is configured to perform data processing on external data DQ in response to the first internal strobe signal PDS and the second internal strobe signal PDSD to generate internal write data LATO<0:3>.

The data strobe buffer 220 is configured to buffer the data strobe signal DQS to generate the first internal strobe signal PDS. The inverter 293 is configured to invert the test mode signal HSC. The second AND gate 291 is configured to perform a logical AND operation on the write signal WRITE and an output signal of the inverter 293. The first frequency divider 280 is configured to divide a frequency of the first internal strobe signal PDS by a first dividing ratio to generate a first frequency-divided strobe signal PDS_DIV1 in response to an output signal of the second AND gate 291. The second frequency divider 285 is configured to divide a frequency of the first internal strobe signal PDS by a second dividing ratio to generate a second frequency-divided strobe signal PDS_DIV2 in response to an output signal of the third AND gate 292. The first AND gate 290 is configured to perform a logical AND operation on the first internal strobe signal PDS, the first frequency-divided strobe signal PDS_DIV1, and the second frequency-divided strobe signal PDS_DIV2 to generate the second internal strobe signal PDSD. Therefore the first frequency divider 280 may be activated to generate the first frequency-divided strobe signal PDS_DIV1 when the test mode signal is disabled whereas the second frequency divider 285 may be activated to generate the second frequency-divided strobe signal PDS_DIV2 when the test mode signal is enabled. As described above, the inverter 293 and the second AND gate 291 may be included in the first frequency divider 280, and the third AND gate 292 may be included in the second frequency divider 285.

The data input buffer 210 is configured to buffer the external data DQ to generate first internal data DIN. The first flip-flop 230 is configured to sample the first internal data DIN in response to the first internal strobe signal PDS to generate second internal data DI<0:1> having 2 bits. The variable delay circuit 240 is configured to delay each bit of the second internal data DI<0:1> in response to the first internal strobe signal PDS and the test mode signal HSC to generate third internal data DID<0:3> having 4 bits. The second flip-flop 250 is configured to rearrange the third internal data DID<0:3> in response to the second internal strobe signal PDSD to generate fourth internal data DIDD<0:3>. The latch circuit 260 is configured to latch the fourth internal data DIDD<0:3> in response to an internal clock signal PCLKW.

Hereinafter, operations of the semiconductor memory device 200 according to an example embodiment of the present invention shown in FIG. 7 will be described.

In the semiconductor memory device 200, the data strobe circuit 202 is different from the circuit shown in FIG. 1.

The first frequency divider 280 is enabled in the normal mode, and divides the first internal strobe signal PDS by BL/2 to generate the first frequency-divided strobe signal PDS_DIV1 in response to the write signal WRITE and the test mode signal HSC. The second frequency divider 285 is enabled in the test mode, and divides the first internal strobe signal PDS by BL/4 to generate the second frequency-divided strobe signal PDS_DIV2 in response to the write signal WRITE and the test mode signal HSC. Here, BL denotes a burst length of a semiconductor memory device. For example, when BL is 4, the first frequency divider 280 divides the first internal strobe signal PDS by two to generate the first frequency-divided strobe signal PDS_DIV 1, and the second frequency divider 285 divides the first internal strobe signal PDS by 1 to generate the second frequency-divided strobe signal PDS_DIV2.

The semiconductor memory device 200 according to an embodiment shown in FIG. 7 is configured to control the first flip-flop 230 and the variable delay circuit 240 included in the data input circuit 204 using the first internal strobe signal PDS that is a buffered signal of the data strobe signal DQS. The data strobe signal DQS is input to the semiconductor memory device 200 in the test mode. Furthermore, in the semiconductor memory device 200 shown in FIG. 7, the parameter tDS/DH may not be changed because the first internal data DIN is sampled using the first internal strobe signal PDS both in the normal mode and in the test mode. Furthermore, similar the circuit shown in FIG. 1, the time period between a rising edge of the second internal strobe signal PDSD and a rising edge of the internal clock signal PCLKW in the test mode is a half clock longer than the time period in the normal mode.

As described above, the semiconductor memory device that includes an input circuit according to an embodiment can generate an internal strobe signal having different enable points of time in a normal mode and in a test mode, and may be tested at high speed using the internal data strobe signal. Furthermore, the semiconductor memory device that includes an input circuit according to an embodiment can use internal data strobe signals divided by a different dividing ratio in the normal mode and in the test mode. As a result, the AC parameters such as tDS/DH and DQSS need not be changed and the test capabilities need not be limited.

While the example embodiments of the present invention and their advantages have been described in detail, it should be understood that various changes, substitutions and alterations may be made herein without departing from the scope of the invention.

What is claimed is:

1. An input circuit for a semiconductor memory device comprising:
a data strobe circuit configured to buffer a data strobe signal to generate a first internal strobe signal and to generate a second internal strobe signal in response to the first internal strobe signal and an operating mode of the semiconductor memory device; and
a data input circuit configured to perform data processing on input data in response to the first internal strobe signal, the second internal strobe signal and the operating mode to generate internal write data.

2. The input circuit of claim 1, wherein the data strobe circuit comprises:
a data strobe buffer configured to buffer the data strobe signal to generate the first internal strobe signal;
a frequency divider configured to divide a frequency of the first internal strobe signal to generate a frequency-divided strobe signal, the frequency divider configured to divide by a first dividing ratio in a normal mode and by a second dividing ratio in a test mode in response to a write signal and a test mode signal;
an AND gate configured to perform a logical AND operation on the first internal strobe signal and the frequency-divided strobe signal; and
a delay unit configured to delay an output signal of the AND gate to generate the second internal strobe signal.

3. The input circuit of claim 2, wherein the first dividing ratio and the second dividing ratio are based on a burst length.

4. The input circuit of claim 2, wherein the second dividing ratio is lower than the first dividing ratio.

5. The input circuit of claim 2, wherein the first dividing ratio is half of a burst length and the second dividing ratio is a fourth of the burst length.

6. The input circuit of claim 1, wherein the data input circuit comprises:
a data input buffer configured to buffer the external data to generate first internal data;
a first flip-flop circuit configured to sample the first internal data in response to the first internal strobe signal to generate second internal data having N bits, N being a positive integer;
a variable delay circuit configured to delay each bit of the second internal data in response to at least one of the first internal strobe signal and a test mode signal to generate third internal data having 2N bits;
a second flip-flop circuit configured to rearrange the third internal data in response to the second internal strobe signal to generate fourth internal data; and
a latch circuit configured to latch the fourth internal data in response to an internal clock signal.

7. The input circuit of claim 6, wherein the second internal data comprises at least one transmission gate configured to be controlled by the first internal strobe signal in a normal mode and configured to be controlled by the test mode signal in a test mode instead of the first internal strobe signal.

8. The input circuit of claim 6, wherein the variable delay circuit comprises:
a first delay path configured to delay a first bit of the second internal data by a first delay time in to generate a first bit of the third internal data;
a second delay path configured to delay a second bit of the second internal data by a second delay time to generate a second bit of the third internal data;
a third delay path configured to delay the first bit of the second internal data by a third delay time to generate a third bit of the third internal data; and
a fourth delay path configured to delay the second bit of the second internal data by a fourth delay time to generate a fourth bit of the third internal data.

9. The input circuit of claim 8, wherein the first delay path comprises:
a first transmission gate configured to transfer the first bit of the second internal data in response to the first internal strobe signal in a normal mode and in a test mode;
a first latch configured to latch an output signal of the first transmission gate;
a second transmission gate configured to transfer an output signal of the first latch in response to the first internal strobe signal in the normal mode and configured to pass the output signal of the first latch without delay in response to the test mode signal in the test mode;
a second latch configured to latch an output signal of the second transmission gate;
a third transmission gate configured to transfer an output signal of the second latch in response to the first internal strobe signal in the normal mode and configured to pass the output signal of the second latch without delay in response to the test mode signal in the test mode;
a third latch configured to latch an output signal of the third transmission gate; and
an inverter configured to invert an output signal of the third latch.

10. The input circuit of claim 8, wherein the second delay path comprises:
a first transmission gate configured to transfer the second bit of the second internal data in response to the first internal strobe signal in a normal mode and configured to pass the second bit of the second internal data without delay in response to the test mode signal in a test mode;
a first latch configured to latch an output signal of the first transmission gate;
a second transmission gate configured to transfer an output signal of the first latch in response to the first internal strobe signal in the normal mode and configured to pass the output signal of the first latch without delay in response to the test mode signal in the test mode;
a second latch configured to latch an output signal of the second transmission gate;
a first inverter configured to invert an output signal of the second latch; and
a second inverter configured to invert an output signal of the first inverter.

11. The input circuit of claim 8, wherein the third delay path comprises:
a transmission gate configured to pass the first bit of the second internal data in response to the first internal strobe signal in a normal mode and in a test mode;
a latch configured to latch an output signal of the transmission gate;
a first inverter configured to invert an output signal of the latch;
a second inverter configured to invert an output signal of the first inverter; and
a third inverter configured to invert an output signal of the second inverter.

12. The input circuit of claim 8, wherein the fourth delay path comprises:
a first inverter configured to invert the second bit of the second internal data;
a second inverter configured to invert an output signal of the first inverter;
a third inverter configured to invert an output signal of the second inverter; and
a fourth inverter configured to invert an output signal of the third inverter.

13. The input circuit of claim 1, wherein the data strobe circuit comprises:
a data strobe buffer configured to buffer the data strobe signal to generate the first internal strobe signal;
a first frequency divider configured to divide a frequency of the first internal strobe signal by a first dividing ratio in response to a write signal and a test mode signal to generate a first frequency-divided strobe signal;
a second frequency divider configured to divide the frequency of the first internal strobe signal by a second dividing ratio in response to the write signal and the test mode signal to generate a second frequency-divided strobe signal; and
an AND gate configured to perform a logical AND operation on the first internal strobe signal, the first frequency-divided strobe signal, and the second frequency-divided strobe signal to generate the second internal strobe signal.

14. The input circuit of claim 13, wherein the first frequency divider is configured to be activated in a normal mode and the second frequency divider is configured to be activated in a test mode.

15. The input circuit of claim 1, wherein the data strobe circuit comprises:
a data strobe buffer configured to buffer the data strobe signal to generate the first internal strobe signal;
an inverter configured to invert a test mode signal;
a first AND gate configured to perform a logical AND operation on a write signal and an output signal of the inverter;
a second AND gate configured to perform a logical AND operation on the write signal and the test mode signal;
a first frequency divider configured to divide a frequency of the first internal strobe signal by a first dividing ratio in response to an output signal of the first AND gate to generate a first frequency-divided strobe signal;
a second frequency divider configured to divide the frequency of the first internal strobe signal by a second dividing ratio in response to an output signal of the second AND gate to generate a second frequency-divided strobe signal;
a third AND gate configured to perform a logical AND operation on the first internal strobe signal, the first frequency-divided strobe signal, and the second frequency-divided strobe signal; and
a delay unit configured to delay an output signal of the third AND gate to generate the second internal strobe signal.

16. The input circuit of claim 1, wherein the second internal strobe signal is enabled at a different point in time in a normal mode and in a test mode.

17. A semiconductor memory device comprising:
a data strobe circuit configured to buffer a data strobe signal to generate a first internal strobe signal and to generate a second internal strobe signal in response to the first internal strobe signal and a test mode signal;
a first flip-flop circuit configured to retime input data into first internal data having a plurality of bit streams;
a delay circuit configured to delay the first internal data in response to at least one of the first internal strobe signal and the test mode signal to generate second internal data;
a second flip-flop circuit configured to retime the second internal data in response to the second internal strobe signal to generate third internal data; and
a memory cell array configured to store the third internal data.

18. The semiconductor memory device of claim 17, wherein the data strobe circuit comprises:
a data strobe buffer configured to buffer the data strobe signal to generate the first internal strobe signal;
a frequency divider configured to divide a frequency of the first internal strobe signal by a dividing factor to generate a frequency-divided strobe signal; and
an logic circuit configured to combine the first internal strobe signal and the frequency-divided strobe signal to generate the second internal strobe signal;
wherein the dividing factor is responsive to the test mode signal.

19. The semiconductor memory device of claim 17, wherein the delay circuit is configured to delay the first internal data to generate the second internal data such that bits of the second internal data are aligned with the second internal strobe signal.

20. The semiconductor memory device of claim 19, wherein the delay circuit is configured to delay the first internal data such that:
in a normal mode, each bit in a burst length of the input data appears on a corresponding input of the second flip-flop circuit substantially simultaneously as other bits in the burst length; and
in a test mode, each bit in the burst length of the input data appears on a corresponding plurality of inputs of the second flip-flop circuit substantially simultaneously as other bits in the burst length.

21. A method of controlling an input circuit of a semiconductor memory device comprising:
receiving input data;
generating a first internal strobe signal in response to a data strobe signal;
delaying bits of the input data in response to the first internal strobe signal and an operating mode of the semiconductor memory device;
generating a second internal strobe signal in response to the first internal strobe signal and the operating mode of the semiconductor memory device;
sampling the delayed bits using the second internal strobe signal; and
storing the sampled bits.

22. The method of claim 21, wherein the operating mode includes a test mode and a normal mode.

23. The method of claim 21, further comprising:
dividing the first internal strobe signal by a dividing factor to generate the second internal strobe signal, the dividing factor being based on the operating mode.

24. The method of claim 23, wherein the dividing factor is a burst length divided by 2 in a normal mode and the burst length divided by 4 in a test mode, the operating mode including the normal mode and the test mode.

25. The method of claim 21, further comprising:
delaying each bit of the input data by a corresponding number of half-periods of the first internal strobe signal.
